(19) United States
(12) Patent Application Publication
(10) Pub. No.: US 2026/0190302 A1
(43) Pub. Date: Jul. 2, 2026

(54) SYSTEMS AND METHODS FOR INTEGRATED COOLING, POWER, AND THERMAL STORAGE FOR DATACENTERS

(71) Applicant: Orion Digital Infrastructure LLC, Jacksonville, FL (US)

(72) Inventors: Ossama Abbas Fathy ABDALLA, Jacksonville, FL (US); Brannen Graybill MCELMURRAY, New York, NY (US)

(21) Appl. No.: 19/435,144

(22) Filed: Dec. 29, 2025

Related U.S. Application Data
(60) Provisional application No. 63/740,171, filed on Dec. 30, 2024.

(51) Int. Cl. H05K 7/20; G06Q 10/0631; G06Q 50/06

(52) U.S. Cl. CPC H05K 7/20836; G06Q 10/06315; G06Q 50/06; H05K 7/20781

(57) ABSTRACT

A method and system are provided for integrated power and thermal management of a datacenter. The method includes receiving, from a power plant, electrical energy. The method further includes modifying, by a thermal modification plant and using the electrical energy, a temperature of a thermal transfer fluid to generate a temperature-modified thermal transfer fluid. The method also includes storing, in a thermal storage structure, the temperature-modified thermal transfer fluid. The method additionally includes transferring at least a portion of the temperature-modified thermal transfer fluid from the thermal storage structure to the datacenter to perform a thermal management operation at the datacenter.

### CROSS-REFERENCE TO RELATED APPLICATIONS

The present application claims priority to U.S. Provisional Patent Application 63/740,171, filed Dec. 30, 2024, the entire disclosure of which is incorporated by reference herein.

### TECHNICAL FIELD

Aspects of the present disclosure relate generally to an integrated cooling, power, and thermal storage for datacenters.

### BACKGROUND

In recent years, the need for new and more powerful datacenters has been driven by a proliferation of computing intensive technology such as artificial intelligence (AI), machine-learning (ML), and digital currency mining. Advances in computer processing speed, volume, and data storage to support these technologies has resulted in the energy consumption growth in order to power and cool these datacenters. Unlike many other power consumptive human activities with relatively stable or slowly changing power requirements, demand for and use of computing power at datacenters can be highly variable based on load (zero to hundreds of megawatts), timing, and duration due to demand may change on the order of fractions of a second, seconds, or minutes. Additionally, in electromechanical systems such as power plants, changes in torque and/or momentum of various parts due to rapid changes in power demands can cause stress to various components of the electromechanical system, including equipment damage due to overheating, premature wear and tear, and failure of sensitive electronics; performance degradation leading to reduced performance, data errors, and data corruption; increased maintenance costs due to damage; and the introduction and/or exacerbation of surges, sags, harmonics issues, frequency regulation and voltage regulation problems. In some instances, this can lead to catastrophic system failures caused by cascading and result in brownouts or blackouts, and/or total system collapse. Accordingly, the development and consistent operation of stable datacenters can pose significant challenges for businesses, public infrastructure, and private infrastructure, including energy consumption and related thermal management issues, due to the intensive and highly variable physical demands of operating such advanced computing infrastructure.

Hence, there is a need to provide energy solutions that increase the operational, economic, and environmental efficiency of datacenters.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. The sole purpose of the summary is to present some concepts of one or more aspects in a simplified form as a prelude to the more detailed description that is presented later.

According to an aspect of the present disclosure, a method is provided for integrated power and thermal management of a datacenter. The method includes receiving, from a power plant, electrical energy. The method further includes modifying, by a thermal modification plant and using the electrical energy, a temperature of a thermal transfer fluid to generate a temperature-modified thermal transfer fluid. The method also includes storing, in a thermal storage structure, the temperature-modified thermal transfer fluid. The method additionally includes transferring at least a portion of the temperature-modified thermal transfer fluid from the thermal storage structure to the datacenter to perform a thermal management operation at the datacenter.

According to another aspect of the present disclosure, a system is provided for integrated power and thermal management of a datacenter. The system includes a thermal modification plant configured to use electrical energy received from a power plant to modify a temperature of a thermal transfer fluid to generate a temperature-modified thermal transfer fluid. The system also includes a thermal storage structure configured to store the temperature-modified thermal transfer fluid. The system additionally includes one or more thermal distribution channels configured to transfer at least a portion of the temperature-modified thermal transfer fluid from the thermal storage structure to the datacenter to perform a thermal management operation at the datacenter.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings provided to illustrate and not to limit the disclosed aspects, wherein like designations denote like elements, and in which.

FIG. 1 is diagram showing an example energy system configured for integrated cooing, power, and thermal storage in accordance with an example aspect.

FIG. 2A is a graph showing conventional power generation with datacenter power usage.

FIG. 2B is a graph showing example power generation with datacenter power usage, in accordance with an example aspect.

FIG. 3 is a flowchart diagram showing integrated power and thermal management of one or more datacenters, in accordance with an example aspect.

FIG. 4 is a flowchart diagram showing additional aspects for integrated power and thermal management of one or more datacenters, in accordance with an example aspect.

FIG. 5 is a diagram showing a computing device, in accordance with an example aspect.

### DETAILED DESCRIPTION

Aspects of the present disclosure are directed to systems and methods for integrated cooling, power, and thermal storage for datacenters.

Existing datacenters, sometimes referred to as server farms, may receive power from utilities such as renewables and thermal plants (e.g., fossil fuel and/or nuclear) and about half of the power received is used for cooling computing infrastructure, while the other half of the power received is used to run computing infrastructure.

Aspects of the present disclosure reduce the fraction of instantaneous electrical power consumed for cooling by decoupling cooling production from cooling consumption and by actively coordinating power generation, thermal storage, and datacenter cooling demand. In short, aspects of the present disclosure shift much of the cooling “work” to times when electricity is abundant or cheaper, stores that cooling as thermal energy, and then delivers chilled fluid to the datacenter when needed without drawing the same level of real-time or near real-time electrical power. This allows a larger share of the available power to be used for computing rather than cooling, especially during peak or fast-ramping artificial intelligence (AI) graphics processing unit (GPU) workloads.

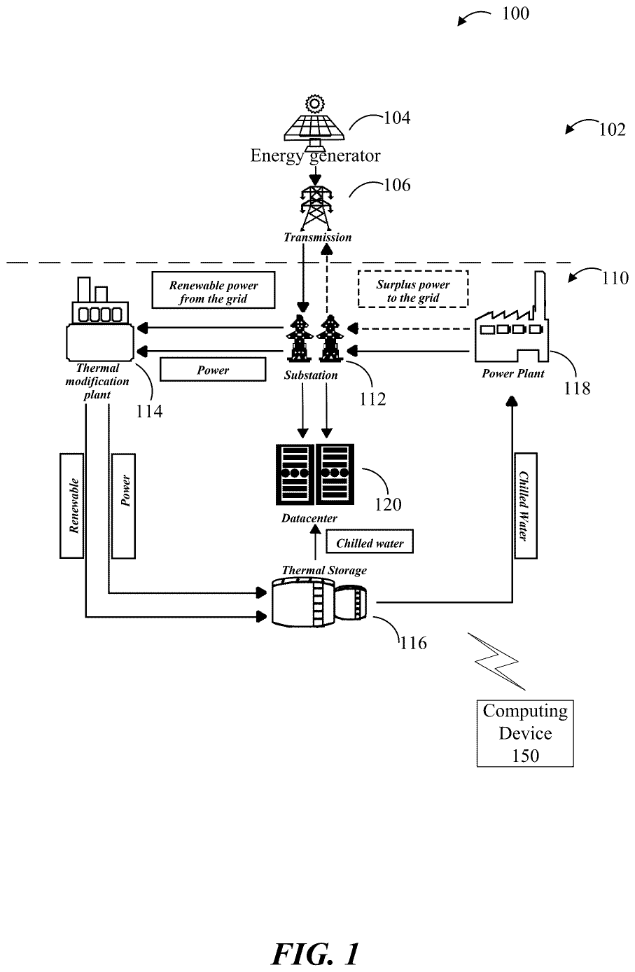

A description will now be given of various aspects of the present disclosure, as they relate to an energy system such as energy system 100 of FIG. 1 described below.
Thermal energy storage (TES) as a “thermal battery.” An energy system uses cooling plants to produce chilled or temperature-modified fluid and stores the temperature-modified fluid in insulated thermal storage structures at defined temperatures (e.g., chilled fluid at approximately 48° F. and warm return near 77° F.). Since the chilled fluid is produced in advance, the datacenter can meet cooling demand by discharging TES instead of running energy-intensive chillers at that moment.
Integrated controls that prioritize Information Technology (IT) load during peaks. An intelligent control system orchestrates substations, chillers, pumps, valves, storage or any other mechanisms that assist in chilling of the temperature-modified fluid. When the IT load of the datacenter spikes (e.g., AI GPU ramp events), the system sheds or reduces live cooling production and increases TES discharge flow to maintain thermal conditions, thereby increasing electrical capacity for the IT load.
Grid and on-site generation coordination. The system takes power from the electric grid (or grid for short) and/or an on-site power plant. During periods of excess generation or off-peak pricing, the system increases chilled-fluid production to charge TES. During grid peaks or fast ramps, the system implements TES discharge and reduces chiller draw, smoothing electrical demand seen by the grid and on-site plant.
Bidirectional benefits with the power plant. Temperature-modified fluid can also be routed to the power plant for turbine inlet cooling or other plant thermal management, improving plant efficiency and enabling more exportable electric power during critical periods. When TES is discharging to the datacenter, the power plant can divert more electrical output to the grid or the IT load instead of to cooling.

As used herein, “electrical grid” (also referred to as “electric grid” or “utility grid”) means any external electrical network operable to supply electrical energy to, and/or receive electrical energy from, a system or facility. An electrical grid can include, without limitation, one or more of: energy sources and generators, transmission and distribution lines, substations and switchgear, metering and protection equipment, control and communications infrastructure, and market or dispatch interfaces. The electrical grid may be public, private, or a hybrid; AC and/or DC; interconnected or islanded; and may include regional bulk power systems, local distribution networks, microgrids, campus or behind-the-meter networks, and any successors or later-developed equivalents. References to the electrical grid encompass associated operational signals (e.g., price, demand response, or curtailment signals) and interconnection points through which power is imported to or exported from the system.

A description will now be given of operational scenarios that cut the real-time power draw of cooling.
Peak-shaving for cooling: Pre-produce chilled fluid before expected AI/ML workload ramps; during the ramp, chillers idle or run at reduced load, while TES supplies the cooling flow and pressure.
Base-loading of chillers: Run chillers steadily and efficiently to charge TES rather than cycling with IT load volatility; this reduces inefficiency from rapid starts/stops and minimizes coincident electric demand with IT peaks.
Fast ramp response: Upon detection of rapid dP/dt (a rate of change of power over a time duration) in datacenter power, controls automatically increase TES discharge and curtail cooling production, preserving power quality and avoiding voltage/frequency disturbances.
Plant efficiency uplift: Use temperature-modified fluid for turbine inlet cooling at the power plant, increasing mass flow and net plant output compared to ambient conditions, which further offsets the electrical burden of cooling.

By supplying temperature-modified fluid from stored thermal energy during peak IT demand and aligning active cooling production with periods of surplus or lower-impact electricity, the system materially reduces the instantaneous electrical share devoted to cooling. This increases the proportion of available power that can be applied to computing, improves stability for both the datacenter and the grid, and supports better overall efficiency metrics (e.g., improved power usage effectiveness) without sacrificing thermal reliability.

In an aspect, one or more control systems and/or methods can be stored in non-transitory computer readable memory and when executed by one or more processors can actuate valves and/or pumps and perform other operations controlled via electromechanical components and/or subsystems. Various sensors and monitors can gather data and information and provide feedback for real-time management of the system using one or more applicable triggers, thresholds, and ranges.

In an aspect, inputs from a power grid and datacenters operating under a workload that can be used for cooling/thermal management, such as: electrical parameters such as voltage levels, current measurements, power factors, frequency, active power, and reactive power; generation data from each power generating and storage element (e.g., one or more of power plants, fluid cooling plants, and thermal storage levels); load demand data from graphics processing units (GPUs); system status information (e.g., for power lines and/or thermal transmission lines); environmental parameters such as temperature and humidity; fluid dynamics parameters such as differential pressure and flow (e.g., power plant gas flow rate); and performance metrics such as thermal design power, graphics processing unit (GPU) utilization, power usage effectiveness, peak-to-average ratio, peak-to-idle ratio, and/or dP/dt (a rate of change of power over a time duration). An example workload can be an artificial intelligence (AI) workload where the workload relates to artificial intelligence computations, a support workload where the workload relates to supporting a downed or otherwise to be supported or replaced part of the energy system, and so forth.

In an aspect, thermal energy storage (TES) provides a flexible and power-plant controllable peak-reduction and base load capability for a power plant, allowing a system to quickly divert power and/or temperature modified fluid (e.g., chilled water) production in order to meet quick demand changes in data center artificial intelligence (AI) graphics processing unit (GPU load cycles.

In an aspect, a temperature of a temperature-modified fluid can be a specific temperature. A temperature of a warm water storage can be a specific temperature before the temperature of the warm water is modified. A storage capacity can be maintained for a specific amount of time before a temperature naturally changes (i.e., a peak cooling production capacity exists). A fluid for temperature modification can be a particular liquid, a particular gas, or a combination thereof. A flow rate can be a specific amount during a peak production or consumption period. A pressure of the temperature-modified fluid can be a specific amount.

In an aspect, temperature-modified fluid can refer to a cooled or chilled fluid temperature. Input temperature can be a temperature at which the fluid is prepared or otherwise ready to be used for providing cooled energy to a datacenter and/or power plant. In an aspect, this input temperature of the temperature modified fluid ready to be used for providing cooled energy to a datacenter and/or power plant can be the same as or equivalent to an output temperature of fluid from a cooling plant thermal modification plant and/or input, holding, and/or output temperature of a fluid at one or more thermal storage structures.

Thermal storage structures are typically large, insulated tanks designed to reduce thermal loss and maintain the fluid at a target temperature for extended periods. High-efficiency insulation, such as polyurethane foam or vacuum panels, aid in preventing heat exchange with the surrounding environment. Thermal storage structures are integrated with a network of sensors to continuously monitor fluid levels, temperature stratification within the tanks, and pressure.

In an aspect, cooled or chilled fluid storage refers to cool thermal storage using one or more thermal storage structures. In an aspect, cooled/chilled and warm fluid are stored in one or more thermal storage structures and, in some aspects, in the same thermal storage structure(s). As cooled fluid is used (e.g., extracted from thermal storage structure(s) and/or transferred to a datacenter and/or a power plant for one or more cooling operations), warmer fluid is returned to the thermal storage structure(s). In some aspects, cooled and warmed fluids are permitted to mix in the thermal storage structure(s). A fluid content or a level in the thermal storage structure(s) can remain constant and, in some aspects, only a temperature of the fluid in the thermal storage structure(s) may be variable. A thermal storage structure is referred to as depleted when a temperature of fluid in the thermal storage structure approaches or reaches a threshold level, which can be a warm fluid temperature.

While a temperature-modified fluid is described herein, a temperature-modified gas can also be used with the temperature-modified fluid or in place of the temperature modified fluid.

In an aspect, a storage capacity loss can be an energy loss that results from a temperature change of a fluid. For example, a chilled fluid, such as water, can be warmed due to imperfect insulation in a thermal storage structure. An energy loss of 0.5 percent per day can be an example of a normal storage capacity loss in some thermal storage structures. In some aspects, the amount or rate of the storage capacity loss can be negligible for intended operations.

In some aspects, a fluid pressure and a flow rate can have a peak value or a maximum value when measured at a thermal storage structure boundary, referred to as a thermal battery limit. A total flow rate of a temperature-modified fluid (e.g., chilled or cooled water) can be distributed among one or more datacenters 120. A fluid pressure range (e.g., water pressure range) can have a peak or a maximum value at an output of a thermal storage tank inlet or outlet, wherein the value varies based on site-specific factors. For example, site-specific factors include a distance between a thermal storage structure and a datacenter or a power plant, an elevation change, and other factors affecting pressure.

For example, in an aspect, an example of a chilled water input temperature can be approximately 48 degrees Fahrenheit (48° F.), a warm water storage temperature can be approximately 77 degrees Fahrenheit (77° F.), a storage capacity can be four to eight hours of peak cooling production capacity, a working fluid can be demineralized water or a dielectric fluid, a flow rate can be 160,000 or more gallons per minute (GPM) during a peak production or consumption period, and a chilled water pressure can be thirty to fifty pounds per square inch gauge (psig).

FIG. 1 is a block diagram of an example energy system 100 configured for integrated cooling, power, and thermal storage for one or more datacenters, in accordance with an example aspect.

The energy system 100 includes a utility grid portion 102 and an energy system technology portion 110. The energy system technology portion 110 is configured, via one or more interfaces, to couple with and operate in conjunction with the utility grid portion 102.

The utility grid portion 102 represents a conventional power grid, which may be an existing or later-developed utility grid that is public, private, or a combination thereof. The utility grid portion 102 serves as the primary external power source and includes one or more energy generators and associated energy transmission structures configured to transmit, provide, and distribute energy to the energy system technology portion 110.

The energy system technology portion 110 performs integrated functions of cooling, power management, and thermal storage for at least one datacenter 120. Energy system technology portion 110 comprises various subsystems, such as chillers, thermal storage tanks, and power distribution units. These subsystems operate in concert to manage the environmental and power requirements of the datacenter 120. The chillers are configured to produce chilled fluid for cooling operations. The thermal storage tanks provide a buffer capacity for storing chilled or warm fluids. An intelligent control system directs the operation of the components to optimize efficiency and reliability.

In some aspects, the utility grid portion 102 is public, private, or a combination of public and private, and includes one or more energy generators 104 coupled with one or more energy transmission structures 106 configured to transmit, provide, or distribute energy. Examples of the one or more energy generators 104 include renewable energy generators such as solar panels, wind turbines, hydroelectric generators, and geothermal generators, and/or other energy generators that provide renewable energy to the energy system technology portion. In some aspects, examples of the one or more energy generators 104 include non-renewable energy generators such as oil power plants, coal power plants, nuclear power plants, and/or other energy generators that provide non-renewable energy to the energy system technology portions. In some aspects, renewable and non-renewable energy generators are used in combination. Energy transmission structures 106 include, for example, electrical substations to step voltage up or down and electric power transmission lines to carry power over distance.

Thus, types of energy generators capable of being used in accordance with aspects of the present disclosure include the following:
Solar panels: Devices that convert incident solar radiation into electrical energy, including photovoltaic (PV) modules that generate direct current via the photovoltaic effect and, in some implementations, concentrated solar power (CSP) systems that use optical concentrators to produce thermal energy subsequently converted to electricity.
Wind turbines: Electromechanical systems that convert the kinetic energy of moving air into electrical energy by rotating blades coupled through a drivetrain to an electrical generator, including horizontal axis and vertical axis configurations deployed onshore or offshore.
Hydroelectric generators: Systems that convert the potential and/or kinetic energy of water into electrical energy, typically by directing flowing or falling water through a turbine mechanically coupled to an electrical generator, including run of river, reservoir (impoundment), and pumped storage configurations.
Geothermal generators: Systems that extract thermal energy from subsurface formations and convert the thermal energy to electrical energy, including flash steam, dry steam, and binary cycle plants that use geothermal fluids or heat to produce motive steam or drive a working fluid through a heat exchange cycle.
Oil power plants: Thermal power plants that generate electrical energy by combusting petroleum derived fuels (e.g., diesel, heavy fuel oil) in boilers driving steam turbines or in internal combustion or gas turbine prime movers mechanically coupled to electrical generators, optionally in simple cycle or combined cycle configurations.
Coal power plants: Thermal power plants that generate electrical energy by combusting coal to produce high pressure steam that drives a steam turbine coupled to an electrical generator, including subcritical, supercritical, ultra supercritical, and integrated gasification combined cycle (IGCC) implementations.
Nuclear power plants: Facilities that generate electrical energy from heat produced by controlled nuclear fission within a reactor core, the heat being used to produce steam that drives a turbine generator set; implementations include, for example, pressurized water reactors (PWR), boiling water reactors (BWR), and other licensed reactor technologies.

In an aspect, the energy system technology portion 110 can include one or more substations 112, one or more cooling plants 114, one or more thermal storage structures 116, one or more power plants 118, and/or one or more datacenters 120.

Substations 112: Facilities that transform voltage from high to low, or the reverse, or perform other functions such as switching, protection, and control of electrical power. Substations may include transformers, circuit breakers, switchgear, and other equipment to manage and direct the flow of electricity.

Cooling plants 114: Systems that provide cooling capacity, for example, by circulating a chilled fluid. Cooling plants can include chillers, cooling towers, pumps, and heat exchangers to remove thermal energy from a process or space, such as a datacenter.

Water can be used as the temperature-modified fluid. Here are common alternatives to water that can be “temperature modified” and circulated or stored for datacenter cooling and thermal energy storage, grouped by use case and with brief notes on pros/cons:

Aqueous blends (glycols/brines):
Ethylene glycol-water and propylene glycol-water (various concentrations)—lower freezing point; higher viscosity and pumping power; propylene glycol is preferred for lower toxicity.
Salt brines (e.g., sodium chloride or calcium chloride solutions)—deep chill capability and good heat capacity; corrosion control required; typically kept outside white space.

Dielectric liquids for direct chip or immersion cooling:
Synthetic hydrocarbons (e.g., polyalphaolefin/PAO, hydrotreated mineral oils)—nonconductive, stable, moderate viscosity; flammable; good for single phase immersion and cold plates.
Silicone oils (polydimethylsiloxane/PDMS)—wide temperature range, very stable; lower thermal conductivity; typically, higher cost.
Synthetic esters (phosphate esters, polyol esters)—good dielectric properties and lubricity; material compatibility review needed.
Fluorinated engineered fluids (fluoroketones, fluorinated ethers)—nonflammable, dielectric; generally higher cost; supply chain and environmental profiles should be checked.
Bio based dielectric oils—emerging options with improved sustainability; validate long term stability.

Refrigerants for two phase or secondary loops:
HFOs (e.g., low GWP unsaturated fluorocarbons)—used in chillers or pumped two phase systems; low GWP; equipment/material compatibility needed.
Natural refrigerants: ammonia (R717), carbon dioxide (R744), propane/isobutane (R290/R600a)—high efficiency; ammonia is toxic/corrosive (keep in plant room/secondary loop); CO2 requires high pressure hardware; hydrocarbons are flammable.

Phase change working media in TES or secondary loops:
Ice slurry (water with micro ice)—high latent storage density; needs specialized slurry handling and separation for distribution.
Eutectic salt hydrate slurries—tunable melting points; manage phase separation and cycling stability.
Paraffin or other organic PCM emulsions—latent storage at selected setpoints; verify stability and pumpability.

Gaseous fluids (for certain plant side heat exchange):
Air—simple, but low heat capacity; mainly for towers or air side economization.
CO2 or nitrogen (including supercritical CO2 on plant side)—specialized, high pressure; typically, not used inside white space.

High temperature TES media (plant side integration):
Molten nitrate salts—suitable for storing heat (hot side TES) rather than cold; useful if integrating with power plant thermal management.

Selection typically turns on dielectric requirements (inside racks vs. plant side), temperature setpoints/freezing risk, viscosity/pumping power, materials compatibility and corrosion control, flammability/toxicity, environmental profile (GWP/ODP), cost/availability, and whether single phase or two-phase operation is desired.

Thermal storage structures 116: Systems designed to store thermal energy for later use. This can involve storing heat or cold in materials such as water, molten salts, or phase-change materials, allowing for the decoupling of thermal energy generation from thermal energy consumption.

Power plants 118: Industrial facilities for the generation of electric power. Power plants can utilize various energy sources, such as fossil fuels (e.g., natural gas, coal), nuclear energy, or renewable sources (e.g., solar, wind), to drive turbines connected to electrical generators.

Datacenters 120: Facilities that house computer systems and associated components, such as telecommunications and storage systems. Datacenters centralize Information Technology (IT) operations and equipment for the purposes of storing, processing, and disseminating data and applications.

In an aspect, the substation 112, thermal modification plant 114, thermal storage structure 116, datacenters 120, and/or power plant 118 are electrically coupled, directly or indirectly, with each other via electrical wire(s)/cable(s) for electrical power distribution and use. In an aspect, thermal storage structure 116, datacenters 120, and/or power plant 118 can be thermally coupled, directly or indirectly, with each other via thermal distribution channels. In an aspect a thermal distribution channel can include conduits such as pipes, tubes, or other channels through or via which one or more fluids convey thermal power. In an aspect the thermal distribution channels and other associated components can be a closed loop system such that the fluid contained therein is maintained in a fluid path which can be a closed loop fluid system between two or more of thermal modification plant, thermal storage structure 116, datacenters 120, and/or power plant 118.

In an aspect, one or more of the substation 112, the thermal modification plant, the thermal storage structure 116, the datacenters 120, or the power plant 118 are electrically coupled, directly or indirectly, via one or more electrical wires or cables for electrical power distribution and use. In an aspect, one or more of the thermal storage structure 116, the datacenters 120, or the power plant 118 are thermally coupled, directly or indirectly, via one or more thermal distribution channels. A thermal distribution channel can include conduits, for example, pipes, tubes, or other channels through which one or more fluids convey thermal power. In an aspect, the one or more thermal distribution channels and other associated components can form a closed-loop fluid system, wherein a fluid is maintained in a fluid path between two or more of the thermal modification plant, the thermal storage structure 116, the datacenters 120, or the power plant 118.

As shown in FIG. 1, utility grid portion 102 and energy system technology portion 110 can be electrically coupled so that electrical energy can be supplied from the utility grid portion 102 to energy system technology portion 110. In some aspects, when excess electrical energy is produced by and/or otherwise exists in energy system technology portion 110 that is not currently being consumed and/or used in energy system technology portion 110, such excess electrical energy can be supplied from energy system technology portion 110 to utility grid portion 102.

In an aspect, energy produced by energy generators 104 can be transmitted to substation 112 (e.g., a gas insulated substation) via energy transmission structures 106. In an aspect, energy produced by power plant 118 can be transmitted to the substation 112. Energy received at substation 112 from energy generators 104 or the power plant 118 can be transmitted to datacenters 120 for operation of the datacenters 120. In an aspect, energy received at substation 112 from energy generators 104 and/or power plant 118 can be transmitted to thermal modification plant to perform one or more thermal transfer operations. In an aspect, when energy production from energy generators 104 on the utility grid portion 102 datacenters 120 and/or thermal modification plant can receive energy from the energy generators 104 and reduce energy consumption from power plant 118.

In an aspect, thermal transfer operations can include cooling one or more fluids. For example, the one or more fluids can be water, air, or other liquids or gases. The cooled fluid can be stored in one or more thermal storage structures 116, which can be specialized insulated tanks. When energy demand peaks on utility grid portion 102, datacenters 120 can rely on thermal storage from a thermal storage structure 116 instead of relying solely on energy from power plant 118. The thermal storage structure 116 can discharge a temperature-modified fluid (e.g., cooled fluid) to datacenters 120. The temperature-modified fluid can be conveyed to the datacenters 120, thermal modification plant, and/or power plant 118 for one or more cooling operations. For example, a cooling operation at a datacenter 120 can include cooling one or more computer processors or servers. A cooling operation at thermal modification plant can include cooling devices or components that heat up during energy conversion. A cooling operation at power plant 118 can include inlet cooling for air that is directed through turbines. This can increase the mass flow, which in turn can increase power output of power plant 118 as compared to using ambient or untreated air. When a thermal storage structure 116 is discharging, power plant 118 can supply surplus energy to the utility grid portion 102. Thermal modification plant can send chilled water from thermal storage structure 116 to power plant 118 to increase efficiency and generate additional energy to send to utility grid portion 102.

FIG. 1 further shows one or more computing devices 150. In some aspects, a computing device 150 can be one or more computing devices individually or in working combination integrated with and/or electrically coupled with energy system technology portion 110 and collocated with one or more of substation 112, thermal modification plant, thermal storage structure 116, datacenters 120, and/or power plant 118. Accordingly, in some aspects, computing device 150 can receive data about substation 112, thermal modification plant 114, thermal storage structure 116, datacenters 120, and/or power plant 118 via one or more sensors and/or monitoring equipment (not shown). This data can be related to time, power, thermal or other system characteristics and can be used as inputs to one or more software programs running on computing device 150. Computing device 150 can utilize these inputs to maintain and/or modify one or more system characteristics such as device and/or component states, statuses, and/or orientations in the system; fluid characteristics; and electrical characteristics.

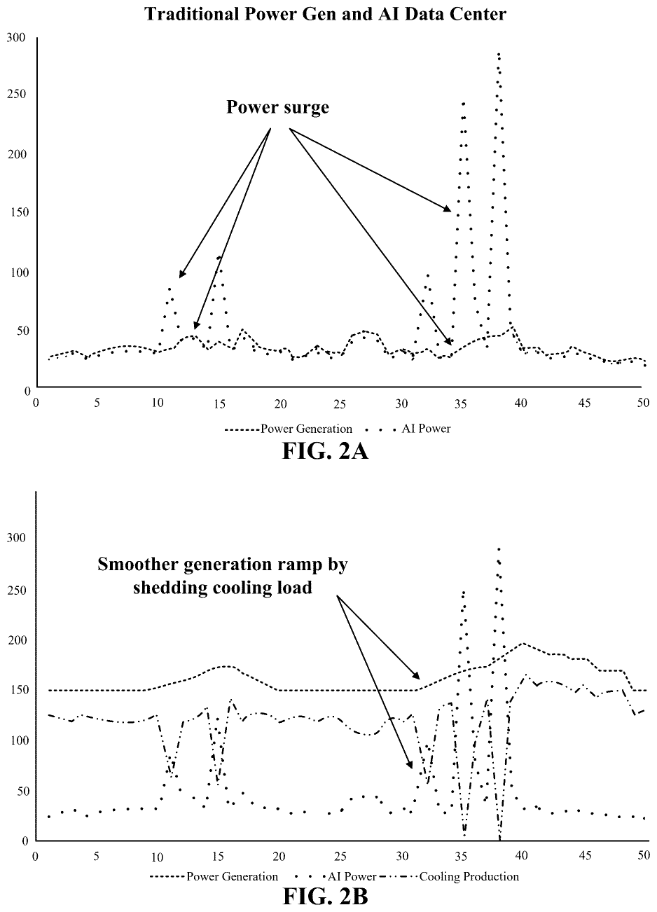

Referring to FIGS. 2A-2B, example graphs illustrate power generation with horizontal axes representing time in seconds and vertical axes representing power in millions of volt-amperes (MVA)

Referring to FIG. 2A, an example power generation and AI datacenter diagram is illustrated. As shown, datacenters, and particularly AI datacenters, can generate power surges (e.g., in an AI Power curve) that far exceed normal power generation characteristics (e.g., a power generation curve) in an energy system.

Referring to FIG. 2B, an example of power generation with cooling production and an AI datacenter diagram is illustrated. As shown, even when datacenters generate power surges (e.g., in an AI Power curve), smoother power generation ramping (e.g., a power generation curve) can be provided by shedding a cooling load (e.g., a cooling production curve), thereby providing more system stability. In an aspect, electrical power and temperature-modified fluid storage can be used to soften and/or smooth drastic electrical power peaks generated by AI/ML or AI-mediated communication (AI/MC) loads. This temperature-modified fluid (e.g., chilled/cooled water) production and thermal energy storage can provide controllable energy and/or power demand and/or buffering to provide electrical power to AI/MC datacenters (e.g., datacenters 120) while preventing and/or without causing an unmanageable shock to power plant(s) and/or generator(s), a utility grid, and/or other devices, components, and/or structures associated therewith.

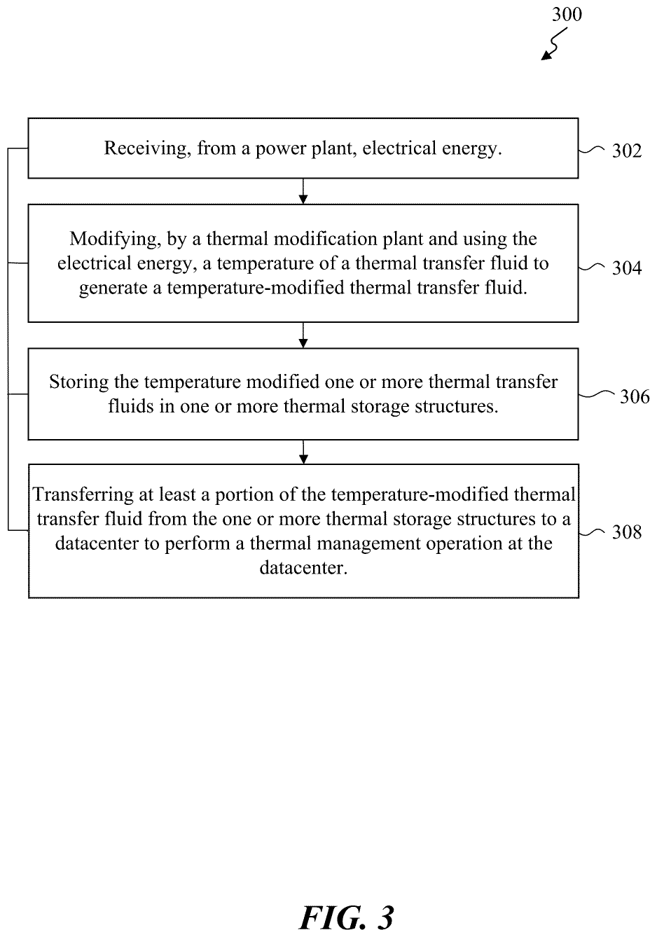

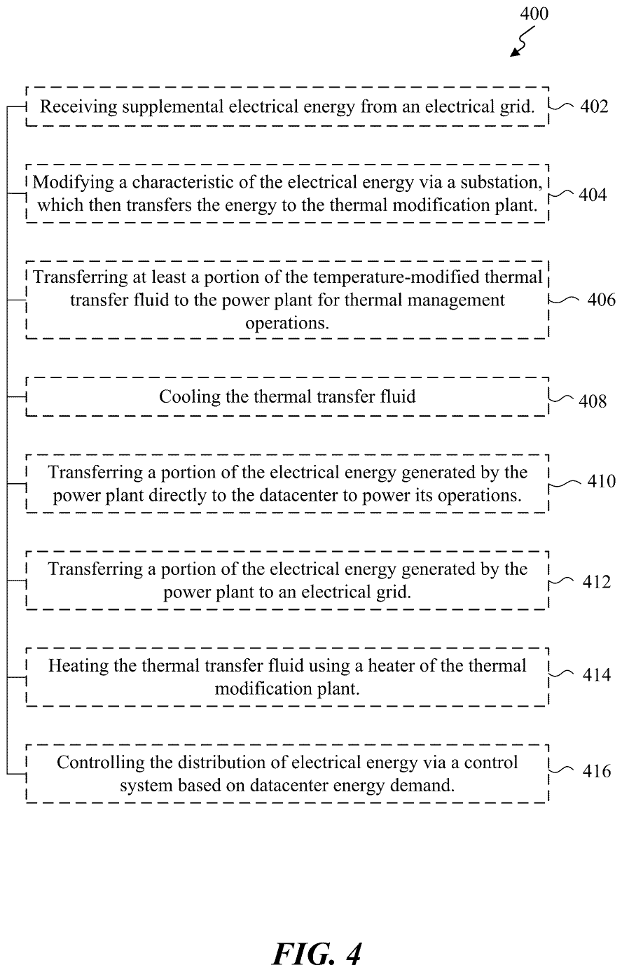

Referring to FIG. 3, an example flowchart of a method 300 for integrated power and thermal management of one or more datacenters is shown. Arrowed lines in FIG. 3 depict an initial flow of blocks of method 300. Non-arrowed lines in FIG. 3 depict subsequent possible flows of blocks of method 300 after the initial flow. Mandatory blocks are shown using solid lines in FIG. 3, and optional blocks are shown using dashed lines in method 400 of FIG. 4.

Block 302 of method 300 includes generating, by a power plant 118, electrical energy. Power plant 118 may be an on-site facility co-located with the datacenter 120 or a remote generator (energy generator 104) connected via transmission infrastructure (energy transmission structures 106). Power plant 118 can utilize a variety of primary energy sources, including natural gas, nuclear fission, or renewable resources such as solar or wind. The electrical energy generated is supplied to both datacenter 120 to power a computational load of datacenter 120 and to thermal modification plant 114 to drive cooling processes. Operationally, the output of the power plant 118 is dynamically controlled in real-time or near real-time (e.g., +/−10 us-100 ms, depending on the application) to match the variable power demands of datacenter 120, particularly during high-intensity AI workloads. This dynamic generation capability allows energy system 100 to respond to rapid changes in load, thereby helping to maintain stability on the broader utility grid.

Block 304 of method 300 includes modifying, by a thermal modification plant 114 and using the electrical energy, a temperature of a thermal transfer fluid to generate a temperature-modified thermal transfer fluid. This process typically involves large-scale refrigeration systems, such as centrifugal or absorption chillers, which use the supplied electrical energy to cool a fluid like water or a glycol mixture to a predetermined setpoint below the ambient temperature. The thermal modification plant 114 can operate continuously or intermittently, often taking advantage of off-peak electricity rates to produce and store large volumes of the cooled fluid. The efficiency of this process is monitored through sensors that measure fluid temperature, flow rates, and energy consumption. This allows for control over the amount of thermal energy stored. Energy system 100 is designed to rapidly produce temperature-modified fluid in response to or in anticipation of high computational loads at datacenter 120.

Block 306 of method 300 includes storing the temperature modified one or more thermal transfer fluids in one or more thermal storage structures 116. This data allows for management of the stored thermal energy, enabling energy system 100 to discharge the cooled fluid precisely when needed to meet the cooling demands of datacenter 120. The storage capacity is sized to function as a thermal buffer, smoothing out discrepancies between the cooling generation and the highly variable cooling load of the datacenter.

Block 308 of method 300 includes transferring at least a portion of the temperature-modified thermal transfer fluid from the one or more thermal storage structures 116 to datacenter 120 to perform a thermal management operation at datacenter 120. This transfer is accomplished using a network of insulated pipes and variable-speed pumps, which modulate flow rate in response to real-time cooling demands. Within the datacenter 120, the fluid circulates through heat exchangers, such as rear-door heat exchangers mounted on server racks or computer room air handlers (CRAHs). As the cooled fluid passes through these units, the cooled fluid absorbs heat generated by the IT equipment, thereby maintaining the equipment within a specified operating temperature range. A control system (computing device 150) continuously monitors supply and return fluid temperatures, flow rates, and server inlet temperatures to optimize the process. After absorbing heat, the now-warmed thermal transfer fluid is returned to the thermal modification plant 114 to be re-cooled, completing the closed-loop cooling cycle.

The transfer of thermal transfer fluid in block 308 can be initiated by several types of triggers, including the following examples:
Temperature-based triggers: The control system (computing device 150) may initiate the transfer when the ambient temperature within datacenter 120 or specific server rack inlet temperatures exceed a predefined threshold. For instance, if a server inlet temperature rises above 25° C., the system can automatically start pumping the temperature-modified fluid to preemptively manage the heat load. To prevent rapid cycling, the system can incorporate a hysteresis band, requiring the temperature to drop significantly below the threshold before ceasing the fluid transfer. This process is further enhanced by utilizing a distributed network of sensors—such as temperature, humidity, and pressure sensors located at server inlets and outlets, within computer room air handlers (CRAHs), and at various points in the fluid circulation path-ensuring that the control decision is based on a comprehensive thermal map of the facility rather than a single point measurement.
Predictive computational load triggers: The control system (computing device 150) may also use predictive analytics to anticipate increases in computational workload (e.g., at about 9:00 AM EST and 9:00 AM PST). By analyzing historical data, network traffic, or scheduled high-performance computing tasks, the system can proactively initiate the transfer of cooled fluid before a significant temperature rise occurs, ensuring thermal stability during peak demand. This predictive capability is often driven by machine learning models that can correlate workload metrics with future thermal output. Furthermore, energy system 100 can interface with the job scheduler of the datacenter 120 to align cooling activation with the dynamic allocation of virtual machines or containerized applications.
Energy cost and availability triggers: The transfer can be triggered based on electricity price signals or the availability of renewable energy. For example, during periods of low electricity cost or high renewable energy generation (as described in block 302), energy system 100 might cool and store a larger volume of temperature-modified fluid. The discharge of this fluid can then be timed to reduce reliance on more expensive cooling methods during peak electricity price periods. This strategy allows the datacenter to participate in demand response programs, earning revenue or incentives by curtailing chiller operation when the grid is strained. The control system may integrate with real-time energy market data feeds to automate these decisions, maximizing economic benefits while maintaining operational integrity.

Referring to FIG. 4, an example flowchart of a method 400 showing additional aspects for integrated power and thermal management of one or more datacenters 120 is shown. Method 400 illustrates optional or alternative steps that can be performed in conjunction with method 300.

Block 402 of method 400 includes receiving supplemental electrical energy from an electrical grid. This optional step can supplement the energy generated in block 302 of method 300, providing additional power resources from an, e.g., an external utility.

Block 404 of method 400 includes modifying a characteristic of the electrical energy via a substation 112, which then transfers the energy to the thermal modification plant 114. This optional step typically occurs between the energy generation of block 302 and the temperature modification of block 304, allowing for voltage transformation or other power conditioning.

Block 406 of method 400 includes transferring at least a portion of the temperature-modified thermal transfer fluid to the power plant 118 for thermal management operations. This optional step represents an alternative use of the fluid stored in block 306, in addition to transferring the fluid to datacenter 120 as described in block 308.

Block 408 of method 400 provides a specific implementation for the process in block 304 of method 300, wherein the thermal modification plant 114 includes a chiller, and the temperature modification includes cooling the thermal transfer fluid.

Block 410 of method 400 includes transferring a portion of the electrical energy generated by the power plant 118 directly to the datacenter 120 to power its operations. This direct transfer can bypass the electrical grid, providing a primary and potentially more reliable power source for the datacenter and increasing overall efficiency of energy system 100 by reducing transmission losses.

Block 412 of method 400 includes transferring a portion of the electrical energy generated by the power plant 118 to an electrical grid. This optional block allows for the sale of surplus energy, creating an additional revenue stream. This capability also enables participation in grid stabilization programs, enhancing the overall economic viability of energy system 100.

Block 414 of method 400 includes heating the thermal transfer fluid using a heater of the thermal modification plant 114. The heating operation can raise the fluid to a defined setpoint to charge hot-side thermal storage, support datacenter reheat or dehumidification or serve power-plant thermal management needs. In some implementations, the heater can be electric resistance, heat-pump based, or waste-heat recovery equipment, and is dispatched by the control system (computing device 150) to maintain stratification, prevent freezing, and align thermal production with off-peak electricity or excess-generation periods.

Block 416 of method 400 includes controlling the distribution of electrical energy via a control system based on datacenter energy demand. This control system, implemented by computing device 150, prioritizes supplying power to the datacenter 120 to meet operational needs of the data center. Based on real-time or near real-time demand, energy system 100 can dynamically allocate electricity from the power plant 118 to the datacenter 120, the electrical grid, or energy storage systems to optimize efficiency and cost.

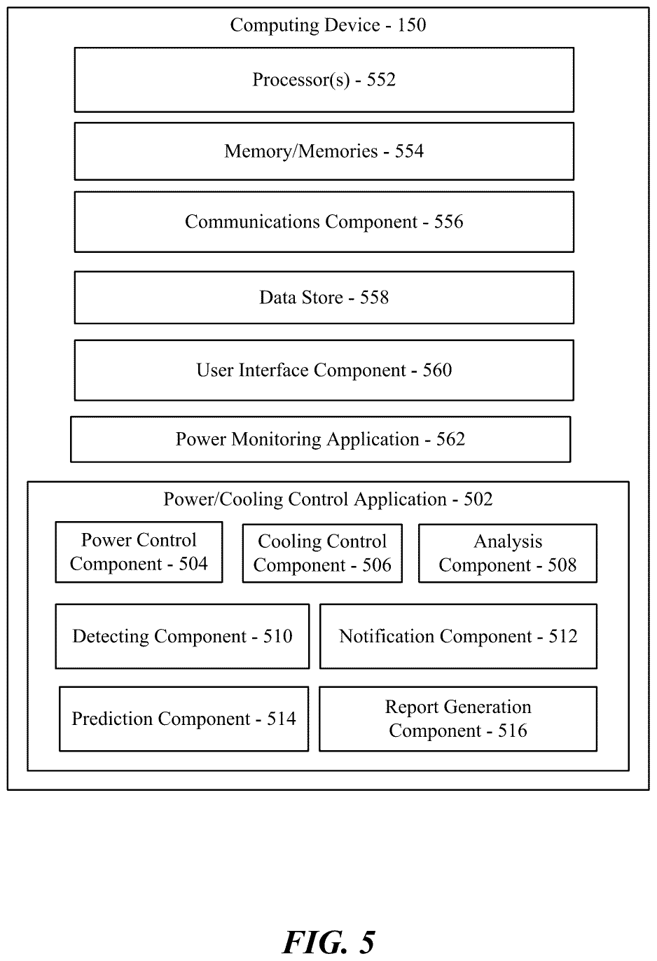

Referring to FIG. 5, a computing device 150 may implement all or a portion of the functionality described herein. The computing device 150 may be or may include or may be configured to implement the functionality of at least a portion of energy system 100, or any component therein. For example, the computing device 150 may be or may include or may be configured to implement a power/cooling control application 502, a power control component 504, a cooling control component 506, an analysis component 508, the detecting component 510, notification component 512, a prediction component 514, and/or a report generation component 516. Computing device 150 includes one or more processors 552 which may be configured to execute or implement software, hardware, and/or firmware modules that perform any functionality described herein. For example, one or more processors 552 may be configured to execute or implement software, hardware, and/or firmware modules that perform any functionality described herein with reference to power/cooling control application 502, power control component 504, cooling control component 506, analysis component 508, detecting component 510, notification component 512, prediction component 514, and/or report generation component 516, or any other component/system/device described herein.

The power/cooling control application 502 can be a software application configured to orchestrate and manage integrated power and thermal management in energy system 100. Power/cooling control application 502 can interface with various components to coordinate the generation of electrical energy, the production of temperature-modified fluid, and the allocation of these resources to one or more datacenters 120. Power/cooling control application 502 may process real-time or near real-time data from power plants 118, thermal modification plants 114, and datacenters 120 to make control decisions. Power/cooling control application 502 can be configured to execute control logic for balancing electrical power supply with datacenter load demands. Furthermore, power/cooling control application 502 can provide a user interface for monitoring system status and configuring operational parameters. Power/cooling control application 502 can also implement algorithms to optimize energy efficiency across the entire energy system 100. Power/cooling control application 502 can further be configured to adapt control strategies based on real-time or near real-time feedback and predictive analytics. This may include adjusting power generation in anticipation of high-demand periods or modifying thermal plant operations based on weather forecasts. Additionally, power/cooling control application 502 can generate historical performance reports and alerts for system anomalies, facilitating proactive maintenance and long-term planning.

The power control component 504 can be a module configured to manage the generation and distribution of electrical power. Power control component 504 may receive data related to current and projected power demand from AI/MC loads within datacenters. Power control component 504 can issue control signals to one or more power plants to adjust electrical energy generation levels. Power control component 504 may also manage the allocation of electrical power between direct datacenter supply and the operation of the thermal modification plant 114. Power control component 504 can operate to stabilize the power grid by modulating power generation in response to fluctuating datacenter workloads. Power control component 504 may also interface with a utility grid to draw or supply power as needed. Power control component 504 can be configured to prioritize power allocation based on predefined rules or real-time conditions.

The cooling control component 506 can be a module configured to manage the production, storage, and transfer of temperature-modified thermal transfer fluids. Cooling control component 506 can regulate the operation of the thermal modification plant 114 to produce chilled or cooled fluid based on anticipated thermal loads. Cooling control component 506 can manage the flow of fluid into and out of one or more thermal storage structures 116, creating a thermal energy buffer. Cooling control component 506 may also control the transfer of the temperature-modified fluid to datacenters for thermal management operations. Cooling control component 506 can be configured to optimize the use of stored thermal energy to meet cooling demands efficiently. Cooling control component 506 can further manage the circulation of the thermal transfer fluid within the datacenters. Cooling control component 506 can adjust fluid flow rates to target specific high-temperature zones within the datacenter.

The analysis component 508 can be a module configured to process operational data from energy system 100. Analysis component 508 may analyze historical and real-time data on power consumption, thermal loads, energy generation, and fluid temperatures. Analysis component 508 can identify trends, patterns, and anomalies in system performance. The output of the analysis can be used by other components to refine control strategies and improve efficiency. For instance, analysis component 508 can determine correlations between specific AI/MC workloads and corresponding power and cooling requirements. Analysis component 508 may generate insights for predictive maintenance of system components. Analysis component 508 can also perform root cause analysis for any detected system failures or inefficiencies.

The detecting component 510 can be a module configured to monitor energy system 100 for specific events or conditions. Detecting component 510 may continuously or semi-continuously or randomly receive sensor data and operational parameters from various system elements, including power plants 118, the utility grid, and datacenters 120. Detecting component 510 can be configured with predefined thresholds to detect conditions such as imminent power spikes, grid instability, or deviations from optimal operating temperatures. Upon detection of such a condition, detecting component 510 can trigger an action, such as activating a notification or initiating a control response. Detecting component 510 serves to identify potential issues before they escalate. Detecting component 510 can also log all detected events for historical analysis. Detecting component 510 can be configured to distinguish between transient fluctuations and persistent problematic conditions.

The notification component 512 can be a module configured to generate and transmit alerts based on system events. Notification component 512 may receive triggers from the detecting component 510 or other system modules when a specific condition is met. Notification component 512 can then formulate a notification message detailing the event, a severity of the event, and relevant data. These notifications can be sent to system administrators or other designated personnel via various communication channels. The purpose of notification component 512 is to provide timely information about system status and critical events to facilitate manual intervention or awareness. Notification component 512 can also manage notification escalation paths based on the severity and type of event. Notification component 512 can be configured to provide different levels of detail in notifications based on recipient roles.

The prediction component 514 can be a module configured to forecast future system states and resource demands. Prediction component 514 may utilize historical data from the analysis component 508 and apply machine learning models or statistical algorithms. Prediction component 514 can forecast future electrical power demand and thermal loads based on scheduled AI/MC workloads, time of day, and other influencing factors. These predictions allow power control component 504 and cooling control component 506 to proactively adjust operations. For example, energy system 100 can pre-cool thermal transfer fluid in anticipation of a large upcoming computational task. The prediction component 514 can continuously refine prediction models based on new data. The prediction component 514 can generate confidence intervals for the forecasts to aid in risk assessment.

The report generation component 516 can be a module configured to compile and format system data into comprehensive reports. Report generation component 516 can aggregate data over specified time periods, such as daily, weekly, or monthly intervals. Report generation component 516 may include information on energy consumption, power usage effectiveness (PUE), thermal storage levels, and system alerts. Reports can be generated automatically on a schedule or on-demand by a user. These reports provide a historical record of system performance and can be used for auditing, capacity planning, and long-term strategic analysis. Report generation component 516 can create customizable report templates for different audiences. Report generation component 516 can also distribute reports automatically to a predefined list of stakeholders.

The one or more processors 552 may be embodied as a central processing unit (CPU), a graphics processing unit (GPU), a micro-controller, an application-specific integrated circuit (ASIC), a digital signal processor (DSP), or a field-programmable gate array (FPGA), and may include a single processor, multiple processors, or multi-core processors. Moreover, the one or more processors 552 may be implemented as an integrated processing system (e.g., a System-on-Chip or SoC) or a distributed processing system. The computing device 150 may further include one or more memories 554 communicatively coupled to the one or more processors 552, for storing executable instructions, parameters, and data. The one or more memories 554 may include any type of non-transitory computer-readable media, such as random-access memory (RAM), read-only memory (ROM), solid-state drives (SSDs), magnetic discs, or optical discs, including both volatile and non-volatile memory. Additionally, the one or more processors 552 and the one or more memories 554 may be configured to execute an operating system, one or more software applications, device drivers, and other software components of the computing device 150.

Further, the computing device 150 may include a communications component 556 that provides for establishing and maintaining communications with other devices and system components. The communications component 556 may carry communications internally between components on the computing device 150 (e.g., via system buses such as Peripheral Component Interconnect Express (PCIe)) and externally with devices across a communications network or those connected locally. In an aspect, the communications component 556 may include hardware such as one or more Network Interface Controllers (NICs) for wired communication using protocols like TCP/IP, wireless transceivers for radio-based communication, and specialized serial interfaces (e.g., RS-485) for industrial control. To interface with power system equipment, the component may be operable to use industrial protocols such as Modbus, DNP3, or SCADA. The communications component may further include transmit chain components and receive chain components associated with wired and wireless transceivers of the communications component for interfacing with external devices.

Additionally, the computing device 150 may include a data store 558, which can be any suitable combination of hardware and/or software, which provides for mass storage of information, databases, and programs. For example, the data store 558 may be or may include a data repository for applications and/or related parameters not currently being executed by one or more processors 552. In addition, the data store 558 may be a data repository for an operating system, application, display driver, etc., executing on the one or more processors 552, and/or one or more other components of the computing device 150.

The computing device 150 may also include a user interface component 560 operable to receive inputs from a user of the computing device 150 and further operable to generate outputs for presentation to the user (e.g., via a display interface to a display device). The user interface component 560 may include one or more input devices, including but not limited to a keyboard, a number pad, a mouse, a touch-sensitive display, a navigation key, a function key, a microphone, a voice recognition component, or any other mechanism capable of receiving an input from a user, or any combination thereof. Further, the user interface component 560 may include one or more output devices, including but not limited to a display interface, a speaker, a haptic feedback mechanism, a printer, any other mechanism capable of presenting an output to a user, or any combination thereof.

A power monitoring application 562 can be a software application configured to monitor and analyze electrical power consumption within energy system 100. Power monitoring application 562 may collect real-time or near real-time data from various points in the system, including the power plant 118, substation 112, and datacenter 120. Power monitoring application 562 can process the collected data to calculate key performance indicators such as power usage effectiveness (PUE) and total energy consumption. Power monitoring application 562 may also identify power quality issues, such as voltage sags, swells, or harmonic distortions. Power monitoring application 562 can generate visualizations and reports to provide insights into energy usage patterns and anomalies. Power monitoring application 562 can integrate with the notification component 512 to send alerts when power parameters exceed predefined safety or efficiency thresholds.

In various aspects, the system can incorporate redundancies and backups to enhance reliability. For energy storage, the system may utilize a dual-redundancy approach, integrating both battery arrays and supercapacitors. This configuration ensures continuous operation, with batteries providing long-term energy supply and supercapacitors managing high-power, short-duration demands. Regarding temperature modification, redundancy can be achieved through parallel cooling circuits or multiple thermoelectric cooling units. A failure in one cooling component would trigger a seamless transition to a backup unit, maintaining optimal operating temperatures without interruption. Additional backup power sources, such as a secondary grid connection or a local generator, can provide further resilience against power failures.

In various aspects, one or more supercapacitors can be integrated into the system to enhance power storage and delivery. These super-capacitors serve a role in managing high-power, short-duration energy demands that are typical during peak processing loads or rapid system state changes. By providing instantaneous power, the super-capacitors complement traditional battery storage, which is better suited for long-term, sustained energy supply. This dual-storage approach creates a more robust and responsive power system, improving overall efficiency and reliability. The integration of super-capacitors allows for quicker charging and discharging cycles compared to batteries, prolonging the lifespan of the entire energy storage infrastructure. This ensures system 100 can manage dynamic power requirements without compromising stability or performance.

In various aspects, software solutions on the data center side can be integrated into the system. For instance, management software can be employed to monitor real-time or near real-time performance metrics, such as energy consumption, component temperatures,

and processing loads. The management software can also include predictive analytics capabilities, using machine learning algorithms to forecast potential hardware failures and optimize maintenance schedules. Furthermore, resource orchestration platforms can dynamically allocate computational and power resources to meet fluctuating demands, ensuring optimal efficiency. Data analytics software could be used to process the data generated by energy system 100, providing valuable insights for capacity planning and operational improvements. Such integration allows for a centralized and intelligent management framework, enhancing the overall reliability, performance, and cost-effectiveness of energy system 100.

Additional aspects of the present disclosure may include one or more of the following clauses.
Clause 1. A method for integrated power and thermal management of a datacenter, the method comprising: receiving, from a power plant, electrical energy; modifying, by a thermal modification plant and using the electrical energy, a temperature of a thermal transfer fluid to generate a temperature-modified thermal transfer fluid; storing, in a thermal storage structure. the temperature-modified thermal transfer fluid; and transferring at least a portion of the temperature-modified thermal transfer fluid from the thermal storage structure to the datacenter to perform a thermal management operation at the datacenter.
Clause 2. The method of clause 1, further comprising receiving, from an electrical grid, supplemental electrical energy.
Clause 3. The method of any preceding clauses, further comprising modifying, by a substation, a characteristic of the electrical energy, wherein the substation transfers the electrical energy from the power plant to the thermal modification plant.
Clause 4. The method of any preceding clauses, further comprising transferring at least a portion of the temperature-modified thermal transfer fluid to the power plant to perform a thermal management operation at the power plant.
Clause 5. The method of any preceding clauses, wherein the thermal modification plant comprises a chiller, and wherein modifying the temperature of the thermal transfer fluid comprises cooling the thermal transfer fluid.
Clause 6. The method of any preceding clauses, wherein the thermal modification plant comprises a heater, and wherein modifying the temperature of the thermal transfer fluid comprises heating the thermal transfer fluid.
Clause 7. The method of any preceding clauses, further comprising transferring a portion of the electrical energy generated by the power plant to an electrical grid.
Clause 8. The method of any preceding clauses, further comprising controlling, via a control system, a distribution of the electrical energy between the thermal modification plant and an electrical grid based on a real-time or near real-time energy demand of the datacenter.
Clause 9. The method of any preceding clauses, wherein the control system determines the distribution of the electrical energy based further on at least one of a price of electricity on the electrical grid, an ambient temperature, and a thermal load of the datacenter.
Clause 10. The method of any preceding clauses, wherein the control system initiates modifying the temperature of the thermal transfer fluid in response to a detected or predicted increase in an information technology (IT) load of the datacenter.
Clause 11. The method of any preceding clauses, wherein the control system initiates modifying the temperature of the thermal transfer fluid in response to detecting a rate of change of power consumption of the datacenter that exceeds a predetermined threshold.
Clause 12. The method of any preceding clauses, wherein the control system initiates modifying the temperature of the thermal transfer fluid during a period of off-peak electricity pricing on the electrical grid.
Clause 13. The method of any preceding clauses, wherein the control system initiates modifying the temperature of the thermal transfer fluid in response to detecting an excess of electrical energy generated by the power plant relative to a current demand.
Clause 14. The method of any preceding clauses, wherein the transferring is initiated when at least one of an ambient temperature within the datacenter or a server rack inlet temperature exceeds a predefined threshold.
Clause 15. The method of any preceding clauses, wherein the transferring is initiated proactively based on a prediction of an increase in a computational workload of the datacenter.
Clause 16. A system for integrated power and thermal management of a datacenter, the system comprising: a thermal modification plant configured to use electrical energy received from a power plant to modify a temperature of a thermal transfer fluid to generate a temperature-modified thermal transfer fluid; a thermal storage structure configured to store the temperature-modified thermal transfer fluid; and one or more thermal distribution channels configured to transfer at least a portion of the temperature-modified thermal transfer fluid from the thermal storage structure to the datacenter to perform a thermal management operation at the datacenter.
Clause 17. The system of clause 16, further comprising an electrical coupling to an electrical grid configured to receive supplemental electrical energy.
Clause 18. The system of any preceding clauses, further comprising a substation configured to modify a characteristic of the electrical energy and transfer the electrical energy from the power plant to the thermal modification plant.
Clause 19. The system of any preceding clauses, wherein the one or more thermal distribution channels are further configured to transfer at least a portion of the temperature-modified thermal transfer fluid to the power plant to perform a thermal management operation at the power plant.
Clause 20. The system of any preceding clauses, wherein the thermal modification plant comprises a chiller configured to cool the thermal transfer fluid.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, apparatuses, and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general-purpose computer, a special-purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps, or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the terms “component,” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution, and a component can be localized on one computer and/or distributed between two or more computers. Also, these components can be executed from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” and “e.g.” are utilized herein to mean serving as an instance or illustration. Any aspect or design described herein as an “example” or referred to in connection with a “such as” clause or “e.g.” is not necessarily to be construed as preferred or advantageous over other aspects or designs described herein. Rather, use of the terms “example” or “such as” or “e.g.” is intended to present concepts in a concrete fashion. The terms “first,” “second,” “third,” and so forth, as used in the claims and description, unless otherwise clear by context, is for clarity only and does not necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Various aspects described herein can be implemented as a method, apparatus, or article of manufacture using special programming as described herein. In addition, various of the aspects disclosed herein also can be implemented by means of program modules or other types of computer program instructions specially configured as described herein and stored in a memory device and executed individually or in combination by one or more processors, or other combination of hardware and software, or hardware and firmware. Such specially configured program modules or computer program instructions, as described herein, can be loaded onto a general-purpose computer, a special-purpose computer, or another type of programmable data processing apparatus to produce a machine, such that the instructions which execute on the computer or other programmable data processing apparatus create a means for implementing the functionality of disclosed herein.

The term “article of manufacture” as used herein is intended to encompass a computer program accessible from any non-transitory computer-readable device, carrier, or media. For example, computer readable media can include but are not limited to magnetic storage devices (e.g., hard drive disk, floppy disk, magnetic strips, or similar), optical discs (e.g., compact disc (CD), digital versatile disc (DVD), blu-ray disc (BD), or similar), smart cards, and flash memory devices (e.g., card, stick, key drive, or similar).

The detailed description set forth herein in connection with the annexed figures is intended as a description of various configurations or implementations and is not intended to represent the only configurations or implementations in which the concepts described herein may be practiced. The detailed description includes specific details for the purpose of providing a thorough understanding of various concepts. However, it will be apparent to those skilled in the art that these concepts may be practiced without these specific details or with variations of these specific details. In some instances, well-known components are shown in block diagram form, while some blocks may be representative of one or more well-known components.

The previous description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method for integrated power and thermal management of a datacenter, the method comprising:
receiving, from a power plant, electrical energy;
modifying, by a thermal modification plant and using the electrical energy, a temperature of a thermal transfer fluid to generate a temperature-modified thermal transfer fluid;
storing, in a thermal storage structure, the temperature-modified thermal transfer fluid; and
transferring at least a portion of the temperature-modified thermal transfer fluid from the thermal storage structure to the datacenter to perform a thermal management operation at the datacenter.

2. The method of claim 1, further comprising receiving, from an electrical grid, supplemental electrical energy.

3. The method of claim 1, further comprising modifying, by a substation, a characteristic of the electrical energy, wherein the substation transfers the electrical energy from the power plant to the thermal modification plant.

4. The method of claim 1, further comprising transferring at least a portion of the temperature-modified thermal transfer fluid to the power plant to perform a thermal management operation at the power plant.

5. The method of claim 1, wherein the thermal modification plant comprises a chiller, and wherein modifying the temperature of the thermal transfer fluid comprises cooling the thermal transfer fluid.

6. The method of claim 1, wherein the thermal modification plant comprises a heater, and wherein modifying the temperature of the thermal transfer fluid comprises heating the thermal transfer fluid.

7. The method of claim 1, further comprising transferring a portion of the electrical energy generated by the power plant to an electrical grid.

8. The method of claim 1, further comprising controlling, via a control system, a distribution of the electrical energy between the thermal modification plant and an electrical grid based on a real-time or near real-time energy demand of the datacenter.

9. The method of claim 8, wherein the control system determines the distribution of the electrical energy based further on at least one of a price of electricity on the electrical grid, an ambient temperature, and a thermal load of the datacenter.

10. The method of claim 8, wherein the control system initiates modifying the temperature of the thermal transfer fluid in response to a detected or predicted increase in an information technology (IT) load of the datacenter.

11. The method of claim 8, wherein the control system initiates modifying the temperature of the thermal transfer fluid in response to detecting a rate of change of power consumption of the datacenter that exceeds a predetermined threshold.

12. The method of claim 8, wherein the control system initiates modifying the temperature of the thermal transfer fluid during a period of off-peak electricity pricing on the electrical grid.

13. The method of claim 8, wherein the control system initiates modifying the temperature of the thermal transfer fluid in response to detecting an excess of electrical energy generated by the power plant relative to a current demand.

14. The method of claim 1, wherein the transferring is initiated when at least one of an ambient temperature within the datacenter or a server rack inlet temperature exceeds a predefined threshold.

15. The method of claim 1, wherein the transferring is initiated proactively based on a prediction of an increase in a computational workload of the datacenter.

16. A system for integrated power and thermal management of a datacenter, the system comprising:
a thermal modification plant configured to use electrical energy received from a power plant to modify a temperature of a thermal transfer fluid to generate a temperature-modified thermal transfer fluid;
a thermal storage structure configured to store the temperature-modified thermal transfer fluid; and
one or more thermal distribution channels configured to transfer at least a portion of the temperature-modified thermal transfer fluid from the thermal storage structure to the datacenter to perform a thermal management operation at the datacenter.

17. The system of claim 16, further comprising an electrical coupling with an electrical grid configured to receive supplemental electrical energy.

18. The system of claim 16, further comprising a substation configured to modify a characteristic of the electrical energy and transfer the electrical energy from the power plant to the thermal modification plant.

19. The system of claim 16, wherein the one or more thermal distribution channels are further configured to transfer at least a portion of the temperature-modified thermal transfer fluid to the power plant to perform a thermal management operation at the power plant.

20. The system of claim 16, wherein the thermal modification plant comprises a chiller configured to cool the thermal transfer fluid.
